(19) United States
(12) Patent Application Publication
(10) Pub. No.: US 2008/0067531 A1
(43) Pub. Date: Mar. 20, 2008

(54) LIGHT EMITTING DIODE HAVING LIGHT DIFFUSION MEMBER AND METHOD FOR MANUFACTURING THE SAME

(75) Inventor: SHAO-HAN CHANG, Taipei Hsien (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Taipei Hsien (TW)

(21) Appl. No.: 11/617,044

(22) Filed: Dec. 28, 2006

(30) Foreign Application Priority Data
Sep. 14, 2006 (CN) 200610200870.9

(51) Int. Cl. H01L 33/00; H01L 21/00

(52) U.S. Cl. 257/98; 257/99; 438/27; 257/E33.073

(57) ABSTRACT

An exemplary light emitting diode (100) includes a light output unit (101), an optical lens (102) and a diffusing layer (103). The optical lens is mounted on the light output unit. The optical lens has a light input surface (1021) facing the light output unit, a recessed top interface (1022) distal from the light input surface, and a light output surface (1023) generally between the light input surface and the top interface. The diffusing layer is formed on the top interface of the optical lens. The diffusing layer is made of resin matrix material and a plurality of light diffusion particles. Methods for manufacturing the light emitting diode are also provided.

### BACKGROUND OF THE INVENTION

1. Field of the Invention

The present invention relates to light emitting diodes; and more particularly to a side-emitting light emitting diode typically employed in a direct type backlight module of a liquid crystal display, and a method for manufacturing the light emitting diode.

2. Discussion of the Related Art

In a liquid crystal display device, liquid crystal is a substance that does not itself radiate light. Instead, the liquid crystal relies on light received from a light source in order to provide displaying of images and data. In the case of a typical liquid crystal display device, a backlight module powered by electricity supplies the needed light.

Typically, a light source of a backlight module is one of the following two types: a cold cathode fluorescence lamp (CCFL), or a light emitting diode (LED). Disadvantages of a CCFL include high energy consumption, low optical uniformity, and poor purity of white light. In addition, after being repeatedly used over time, a brightness of the CCFL becomes degraded and a color of light emitted by the CCFL tends to shift. In general, the service life of a CCFL is about 15,000 to 25,000 hours. Furthermore, a CCFL only covers 75 percent of color space as defined by the National Television Standards Committee (NTSC). Therefore, using a CCFL cannot satisfy the requirements for a high quality color liquid crystal display. Unlike CCFLs, high powered LEDs can cover as much as 105 percent of color space as defined by the NTSC. In addition, these LEDs have other advantages such as low energy consumption, long service life, and so on. Therefore, high power LEDs are better suited for producing high quality color liquid crystal displays.

FIG. 6 illustrates a conventional backlight module 10 using a plurality of LEDs. The backlight module 10 includes a shallow frame 11, an optical plate 14, and a plurality of LEDs 12. The LEDs 12 are regularly arranged on a bottom wall 112 of the frame 11. The optical plate 14 is positioned over the LEDs 12. Light rays emitted by the LEDs 12 are diffused in the optical plate 14, so that substantially planar light is outputted from the optical plate 14.

Each LED 12 includes a light output unit 121, and an optical lens 122 coupled to the light output unit 121. The light output unit 121 includes a base 1211, and a semiconductor chip 1212 fixed on the base 1211. The optical lens 122 includes a light input surface 1221, a top surface 1222 opposite to the light input surface 1221, and a peripheral light output surface 1223 generally between the light input surface 1221 and the top surface 1222. Light rays enter the optical lens 122 through the light input surface 1221, and propagate to the top surface 1222. Many or most of the light rays undergo total internal reflection at the top surface 1223, and then exit the optical lens 122 through the light output surface 1223.

However, a significant proportion of the light rays still escapes from the optical lens 122 through the top surface 1222. This would ordinarily cause a bright area to occur in the optical plate 14 above the LED 12. In order to prevent this problem, the backlight module 10 further includes a transparent plate 13 disposed between the optical plate 14 and the LEDs 12. The transparent plate 13 defines a plurality of reflective layers 131 on a bottom thereof. The reflective layers 131 are positioned in one-to-one correspondence with the LEDs 12. However, precisely positioning the transparent plate 131 according to the LEDs 12 can be very problematic and troublesome, due to the small size of the LEDs 12. Furthermore, the addition of the transparent plate 13 makes the backlight module 10 heavier, and increases manufacturing costs.

Therefore, what is desired is a light emitting diode that can overcome the above-described shortcomings. A method for manufacturing such light emitting diode would also be efficacious.

### SUMMARY

In one aspect, a light emitting diode according to a preferred embodiment includes a light output unit, an optical lens and a diffusing layer. The optical lens is mounted on the light output unit. The optical lens has a light input surface facing the light output unit, a recessed top interface distal from the light input surface, and a light output surface generally between the light input surface and the top interface. The diffusing layer is formed on the top interface of the optical lens. The diffusing layer is made of resin matrix material and a plurality of light diffusion particles.

In another aspect, a preferred method for manufacturing the above-described light emitting diode includes steps of: providing an optical lens, the optical lens including a light input surface, a recessed top interface distal from to the light input surface, and a light output surface generally between the light input surface and the top interface; mixing resin matrix material and light diffusion particles, thereby forming a light diffusing composition; depositing the light diffusing composition on the top interface of the optical lens; solidifying the light diffusing composition to form a light diffusing member on the top interface; and coupling the optical lens with the light diffusing member to the light output unit, such that the light input surface of the optical lens faces the light-emitting semiconductor.

In a further aspect, another preferred method for manufacturing the above-described light emitting diode includes steps of: coupling an optical lens to a light output unit, the optical lens including a light input surface, a recessed top interface distal from the light input surface, and a light output surface generally between the light input surface and the top interface; mixing resin matrix material and light diffusion particles, thereby forming a light diffusing composition; depositing the light diffusing composition on the top interface of the optical lens; and solidifying the light diffusing composition to form a light diffusing member on the top interface of the optical lens with the light-emitting semiconductor.

Other advantages and novel features will become more apparent from the following detailed description of various embodiments, when taken in conjunction with the accompanying drawings.

### BRIEF DESCRIPTION OF THE DRAWINGS

The components in the drawings are not necessarily drawn to scale, the emphasis instead being placed upon clearly illustrating the principles of the present light emitting diode and method for manufacturing the light emitting diode. Moreover, in the drawings, like reference numerals designate corresponding parts throughout the several views, and all the views are schematic.

FIG. 1 is a side cross-sectional view of a light emitting diode having an optical lens according to a first preferred embodiment of the present invention, the light emitting diode including an optical lens and a diffusing member.

FIG. 2 is a side cross-sectional view of a light emitting diode according to a second preferred embodiment of the present invention, the light emitting diode including an optical lens and a diffusing member.

FIG. 3 is a side cross-sectional view of a light emitting diode according to a third preferred embodiment of the present invention, the light emitting diode including an optical lens and a diffusing layer.

FIG. 4 is a side, cross-sectional view of the optical lens of FIG. 3 with a mass of light diffusing composition applied on a top interface thereof, according to one stage in an exemplary method of making the light emitting diode of FIG. 3.

FIG. 5 is similar to FIG. 4, but showing the mass of light diffusing composition changed into a preform of the diffusing layer by a pressing member, according to a subsequent stage in the exemplary method of making the light emitting diode of FIG. 3.

FIG. 6 is a side cross-sectional view of a conventional backlight module having a plurality of light emitting diodes.

### DETAILED DESCRIPTION OF THE PREFERRED EMBODIMENTS

References will now be made to the drawings to describe preferred embodiments of the light emitting diode and method for manufacturing the light emitting diode, in detail.

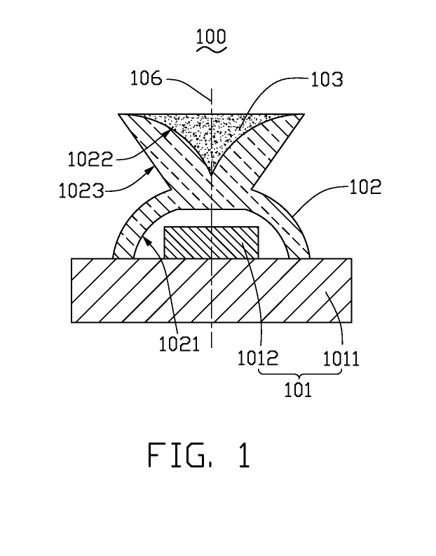

Referring to FIG. 1, a light emitting diode 100 in accordance with a first preferred embodiment of the present invention is shown. The light emitting diode 100 includes a light output unit 101, an optical lens 102, and a light diffusing member 103. The light emitting diode 100 defines a central vertical axis 106, which passes through centers of the light output unit 101 and the optical lens 102. The light output unit 101 includes a base 1011, and a semiconductor chip 1012 fixed on the base 1011. The optical lens 102 includes a light input surface 1021, a recessed top interface 1022, and a peripheral light output surface 1023 generally between with the light input surface 1021 and the top interface 1022. The light input surface 1021 has the shape of a flat-topped dome. The top interface 1022 is funnel-shaped. In the illustrated embodiment, the funnel shape of the top interface 1022 progressively flares out from a bottom of the top interface 1022 to a top of the top interface 1022, with a cross-section of the top interface 1022 taken through the central axis 106 showing two convexities of the top interface 1022.

The light diffusing member 103 is deposited on the top interface 1022 of the optical lens 102. An exposed outer surface (not labeled) of the light diffusing member 103 is configured to be a flat surface parallel to the base 1011 of light output unit 101. The light diffusing member 103 is made of resin matrix material with a plurality of light diffusion particles uniformly distributed in the resin matrix material. The light diffusing member 103 may include the resin matrix material in an amount by weight in the range from 10% to 90%, and the light diffusion particles in an amount by weight in the range from 10% to 90%. The resin matrix material of the light diffusing member 103 may be curing resin, for example, thermal curing resin or ultraviolet light curing resin. A refractive index of the light diffusion particles is in the range from about 1.6 to about 2.75. The light diffusion particles can be selected from the group consisting of titanium dioxide particles, barium sulfate particles, zinc sulfide particles, zinc oxide particles, antimony oxide particles, calcium carbonate particles, and any suitable combination thereof. An average size of the light diffusion particles is in the range from about 0.01 microns to about 5 microns.

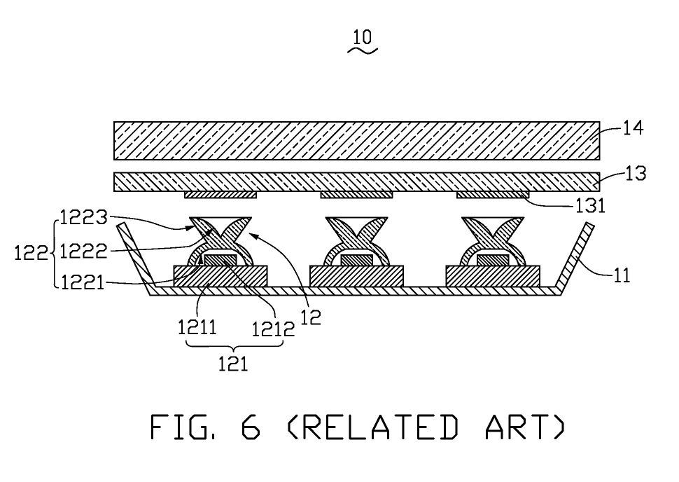

The optical lens 102 is snap-fitted or otherwise mounted onto the base 1012 of the light output unit 101. Thereby, the light input surface 1021 faces the semiconductor chip 1012, and the light input surface 1021 and the base 1011 cooperate to completely surround the semiconductor chip 1012. When light rays emitted by the light output unit 101 enter the optical lens 102 through the light input surface 1021, many or most of the light rays that reach the top interface 1022 are reflected due to interface reflection, and other light rays that escape through top interface 1022 are diffused by the light diffusion particles of the light diffusing member 103. In addition, when a plurality of the light emitting diodes 100 are applied in a backlight module, a distance from the light emitting diodes 100 to an optical plate may be configured to be very small, with little or no risk of bright dots occurring in the optical plate due to reduced intensity of light between adjacent light emitting diodes 100. Furthermore, when compared with the above-described conventional backlight module 10 (FIG. 6), the backlight module utilizing the present light emitting diodes 100 has a relatively lightweight design because a transparent plate such as the transparent plate 13 is not needed.

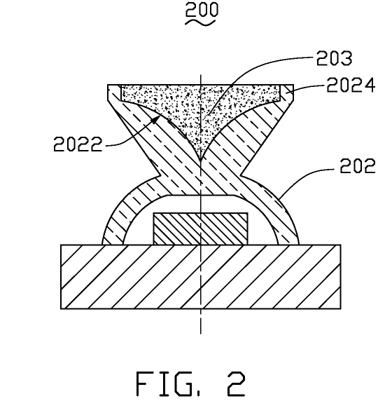

Referring to FIG. 2, a light emitting diode 200 in accordance with a second preferred embodiment of the present invention is shown. The light emitting diode 200 is similar in principle to the light emitting diode 100 of the first embodiment. However, an optical lens 202 further includes a flange ring portion 2024 extending up from a flared funnel-shaped portion thereof. The flared funnel-shaped portion and the flange ring portion 2024 cooperatively define a top interface 2022. The top interface 2022 defines a receptacle (not labeled) for receiving a light diffusing member 203. In this embodiment, the light diffusing member 203 completely fills the receptacle. The flange ring portion 2024 can prevent the light diffusing member 203 from detaching from the top interface 2022 of the optical lens 202, particularly during formation of the light diffusing member 203 in manufacture of the light emitting diode 200.

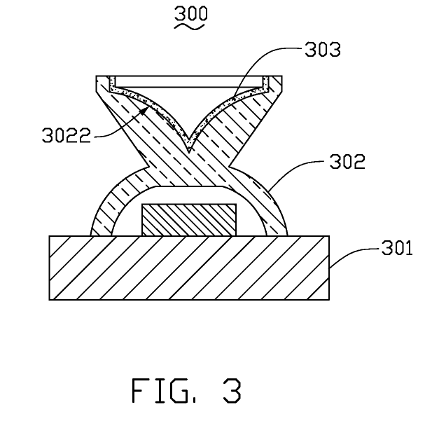

Referring to FIG. 3, a light emitting diode 300 in accordance with a third preferred embodiment of the present invention is shown. The light emitting diode 300 is similar in principle to the light emitting diode 200 of the second embodiment. However, a light diffusing member 303 that covers a funnel-shaped top interface 3022 of an optical lens 302 has a uniform thickness. Therefore, the light diffusing member 303 has a funnel-shaped outer surface corresponding to and distal from the top interface 3022. This configuration means that the light diffusing member 303 has a small volume. Therefore the cost of materials needed to produce the light diffusing member 303 is reduced, and the weight of the light emitting diode 200 is also reduced.

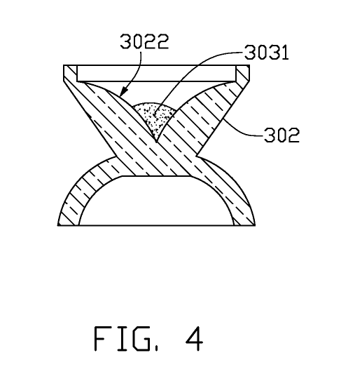

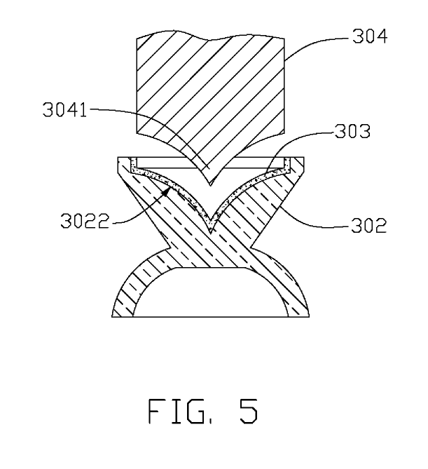

An exemplary method for manufacturing the light emitting diode 300 is as follows. Referring to FIG. 4, firstly, an optical lens 302 is provided, as follows. Secondly, a resin matrix material and a plurality of light diffusion particles are thoroughly mixed together, thereby forming a light diffusing composition 3031. Thirdly, an amount of the light diffusing composition 3031 is deposited on the funnel-shaped top interface 3022 of the optical lens 302, for example by an injector. Fourthly, also referring to FIG. 5, a pressing member 304 having a pressing stamp 3041 is provided to press the light diffusing composition 3031. A shape of the pressing stamp 3041 is general conical and matches with the funnel-shaped top interface 3022. The pressing stamp 3041 of the pressing member 304 is applied to press the light diffusing composition 3031 on the funnel-shaped top interface 3022, so that the light diffusing composition 3031 has a uniform thickness. Fifthly, the light diffusing composition 3031 is solidified, thereby forming the light diffusing member 303 on the top interface 3022 of the optical lens 302. For example, the solidifying is performed by thermal curing or ultraviolet light curing, according to the type of resin matrix material used. Finally, the optical lens 302 having the light diffusing member 303 is coupled to the light output unit 301 to form the light emitting diode 300.

An exemplary method for manufacturing the light emitting diode 200 is similar to the above-described method of manufacturing the light emitting diode 300. The main difference is that the fourth step of using the pressing member 304 is omitted. Instead, the light diffusing composition 3031 completely fills up the receptacle of the optical lens 202.

Another exemplary method for manufacturing the light emitting diode 300 is also provided, as follows. Firstly, an optical lens 302 is coupled to a light output unit 301 to form a subassembly. Secondly, a resin matrix material and a plurality of light diffusion particles are thoroughly mixed together, thereby forming a light diffusing composition 3031. Thirdly, an amount of the light diffusing composition is deposited on the funnel-shaped top interface 3022 of the optical lens 302, for example by an injector. Fourthly, a pressing member 304 having a pressing stamp 3041 is applied to press the light diffusing composition 3031 on the funnel-shaped top interface 3022, so that the light diffusing composition 3031 has a uniform thickness. Finally, the light diffusing composition 3031 is solidified, so as to form the light diffusing member 303 on the top interface 3022 of the optical lens 302. Thereby, the light emitting diode 300 is formed.

Another exemplary method for manufacturing the light emitting diode 200 is similar to the above-described other method for making the light emitting diode 300. The main difference is that the fourth step of using the pressing member 304 is omitted. Instead, the light diffusing composition 3031 completely fills up the receptacle of the optical lens 202.

It is to be noted that the shape of the optical lens is not limited to the above-described embodiments. Other suitable shapes can be configured. Further, in any of the above-described embodiments, a ratio by weight of the light diffusion particles to the resin matrix material of the light diffusing composition can be configured to obtain a desired light diffusion characteristic for the light diffusing member, or be configured to obtain a desired semi-transmission characteristic for the light diffusing member.

Finally, while various embodiments have been described and illustrated, the invention is not to be construed as being limited thereto. Various modifications can be made to the embodiments by those skilled in the art without departing from the true spirit and scope of the invention as defined by the appended claims.

What is claimed is:

1. A light emitting diode comprising:
a light output unit;
an optical lens mounted on the light output unit, the optical lens comprising:
a light input surface facing the light output unit,
a recessed top interface distal from the light input surface, and
a light output surface generally between the light input surface and the top interface; and
a diffusing member formed on the top interface of the optical lens, the diffusing member made of resin matrix material and a plurality of light diffusion particles distributed in the resin matrix material.

2. The light emitting diode according to claim 1, wherein the light diffusing member comprises the resin matrix material in an amount by weight in the range from 10% to 90%, and the light diffusion particles in an amount by weight in the range from 10% to 90%.

3. The light emitting diode according to claim 1, wherein a refractive index of the light diffusion particles is in the range from about 1.6 to about 2.75.

4. The light emitting diode according to claim 1, wherein the light diffusion particles are selected from the group consisting of titanium dioxide particles, barium sulfate particles, zinc sulfide particles, zinc oxide particles, antimony oxide particles, calcium carbonate particles, and any combination thereof.

5. The light emitting diode according to claim 1, wherein an average size of the light diffusion particles is in the range from about 0.01 microns to about 5 microns.

6. The light emitting diode according to claim 1, wherein the light input surface of the optical lens has the shape of a flat-topped dome.

7. The light emitting diode according to claim 1, wherein the optical lens further comprises a flange ring portion at a top end of the top interface.

8. The light emitting diode according to claim 1, wherein the top interface is generally funnel-shaped.

9. The light emitting diode according to claim 8, wherein the light diffusing member fills up the funnel-shaped top interface.

10. The light emitting diode according to claim 8, wherein the light diffusing member has a uniform thickness.

11. A method for manufacturing a light emitting diode, comprising:
providing an optical lens, the optical lens including a light input surface, a recessed top interface distal from the light input surface, and a light output surface generally between the light input surface and the top interface;
mixing resin matrix material and light diffusion particles, thereby forming a light diffusing composition;
depositing the light diffusing composition on the top interface of the optical lens;
solidifying the light diffusing composition to form a light diffusing member on the top interface; and
coupling the optical lens with the light diffusing member to a light output unit, such that the light input surface of the optical lens faces the light output unit.

12. The method according to claim 11, further comprising pressing the light diffusing composition deposited on the top interface of the optical lens by using a pressing member, so that the deposited light diffusing composition has a uniform thickness.

13. The method according to claim 11, wherein solidifying the light diffusing composition is performed by one of a thermal curing process and an ultraviolet light curing process.

14. A method for manufacturing a light emitting diode, comprising:
coupling an optical lens to a light output unit, the optical lens including a light input surface, a recessed top interface distal from the light input surface, and a light output surface generally between the light input surface and the top interface;
mixing resin matrix material and light diffusion particles, thereby forming a light diffusing composition;
depositing the light diffusing composition on the top interface of the optical lens; and
solidifying the light diffusing composition to form a light diffusing member on the top interface of the optical lens with the light output unit.

15. The method according to claim 14, further comprising pressing the light diffusing composition deposited on the top interface of the optical lens by using a pressing member, so that the deposited light diffusing composition has a uniform thickness.

16. The method according to claim 14, wherein solidifying the light diffusing composition is performed by one of a thermal curing process and an ultraviolet light curing process.
